(19) United States
(12) Patent Application Publication
(10) Pub. No.: US 2025/0331338 A1
(43) Pub. Date: Oct. 23, 2025

(54) MULTI-LAYER REFLECTIVE STRUCTURES FOR LIGHT-EMITTING DIODE CHIPS AND RELATED METHODS

(71) Applicant: CreeLED, Inc., Durham, NC (US)

(72) Inventors: Seth Joseph Balkey, Durham, NC (US); Michael Check, Holly Springs, NC (US); Kevin Haberern, Cary, NC (US); Steven Wuester, Wake Forest, NC (US)

(21) Appl. No.: 18/887,256

(22) Filed: Sep. 17, 2024

Related U.S. Application Data
(60) Provisional application No. 63/637,431, filed on Apr. 23, 2024.

(51) Int. Cl. H01L 33/46

(52) U.S. Cl. CPC H10H 20/841; H10H 20/034

(57) ABSTRACT

Solid-state lighting devices including light-emitting diodes (LEDs) and more particularly multiple layer reflective structures for LED chips and related methods are disclosed. Multiple layer reflective structures include different metal reflective layers formed of the same metal but with different morphologies and/or grain structures. Exemplary structures include a first metal reflective layer formed by sputtering, and a second metal reflective layer of the same material and formed by a deposition process different from sputtering. Reflective structures may further include capping layers and/or nucleation layers between the first and second metal reflective layers of the same material.

### RELATED APPLICATIONS

This application claims the benefit of provisional patent application Ser. No. 63/637,431, filed Apr. 23, 2024, the disclosure of which is hereby incorporated herein by reference in its entirety.

### FIELD OF THE DISCLOSURE

The present disclosure relates to solid-state lighting devices including light-emitting diodes (LEDs) and more particularly to multiple layer reflective structures for LED chips and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An active region may be fabricated, for example, from silicon carbide, gallium nitride, gallium phosphide, aluminum nitride, and/or gallium arsenide-based materials and/or from organic semiconductor materials. Photons generated by the active region are initiated in all directions.

Typically, it is desirable to operate LEDs at the highest light emission efficiency, which can be measured by the emission intensity in relation to the output power (e.g., in lumens per watt). A practical goal to enhance emission efficiency is to maximize extraction of light emitted by the active region in the direction of the desired transmission of light. Light extraction and external quantum efficiency of an LED can be limited by how well current is able to spread within an LED and by internal absorption of photons that fail to exit LED chip structures.

As advancements in modern LED technology progress, the art continues to seek improved LEDs and solid-state lighting devices having desirable illumination characteristics capable of overcoming challenges associated with conventional lighting devices.

### SUMMARY

The present disclosure relates to solid-state lighting devices including light-emitting diodes (LEDs) and more particularly to multiple layer reflective structures for LED chips and related methods. Multiple layer reflective structures include different metal reflective layers formed of the same metal but with different morphologies and/or grain structures. Exemplary structures include a first metal reflective layer formed by sputtering, and a second metal reflective layer of the same material and formed by a deposition process different from sputtering. Reflective structures may further include capping layers and/or nucleation layers between the first and second metal reflective layers of the same material.

In one aspect, an LED chip comprises: an active LED structure comprising an n-type layer, a p-type layer, and an active layer between the n-type layer and the p-type layer; and a reflective structure on the active LED structure, the reflective structure comprising: a first metal reflective layer on the active LED structure, the first metal reflective layer comprising a first morphology; and a second metal reflective layer on the active LED structure, the second metal reflective layer comprising a same metal as the first metal reflective layer and a second morphology that is different than the first morphology. In certain embodiments, the first morphology comprises a larger grain size than the second morphology. The LED chip may further comprise a capping layer between the first metal layer and the second metal layer, the capping layer comprising a different metal than the metal of the first and second metal reflective layers. In certain embodiments, the metal of the first and second metal reflective layers comprises silver, and the metal of the capping layer comprises ruthenium, rhodium, palladium, osmium, iridium, platinum, or gold. In certain embodiments, the metal of the first and second metal reflective layers comprises silver, and the metal of the capping layer comprises titanium, nickel, or tungsten. The LED chip may further comprise a nucleation layer between the second metal reflective layer and the capping layer. In certain embodiments, the first metal reflective layer comprises a sputtered metal layer. In certain embodiments, the first metal reflective layer comprises a physical vapor deposited layer. In certain embodiments, the second metal reflective layer is thicker than first metal reflective layer. The LED chip may further comprise a dielectric reflective layer between the first metal reflective layer and the active LED structure, wherein a lateral edge of the second metal reflective layer is inset relative to a lateral edge of the first metal reflective layer on the dielectric reflective layer.

In another aspect, an LED chip comprises: an active LED structure comprising an n-type layer, a p-type layer, and an active layer between the n-type layer and the p-type layer; and a reflective structure on the active LED structure, the reflective structure comprising: a first metal reflective layer on the active LED structure, the first metal reflective layer formed of a first metal; and a capping layer on the first metal reflective layer, the capping layer comprising a noble metal that is different than the first metal. In certain embodiments, the noble metal comprises ruthenium, rhodium, palladium, osmium, iridium, platinum, or gold. In certain embodiments, the first metal comprises silver or a silver alloy. In certain embodiments, the reflective structure further comprises a second metal reflective layer formed of the first metal, and the capping layer is between the first metal reflective layer and the second metal reflective layer. In certain embodiments, the first metal reflective layer comprises a different morphology than the second metal reflective layer. In certain embodiments, the first metal comprises silver and the noble metal comprises gold. The LED chip may further comprise a nucleation layer between the second metal reflective layer and the capping layer. In certain embodiments, the second metal reflective layer is at least the same thickness as the first metal reflective layer and up to ten times thicker than first metal reflective layer.

In another aspect, a method comprises: providing an active light-emitting diode (LED) structure comprising an n-type layer, a p-type layer, and an active layer between the n-type layer and the p-type layer; depositing a first metal reflective layer on the active LED structure with a first deposition process; and depositing a second metal reflective layer on the first metal reflective layer with a second deposition process that is different than the first deposition process, the first metal reflective layer and the second metal reflective layer comprising silver. In certain embodiments, the first deposition process comprises sputtering and the second deposition process comprises electron beam deposition. In certain embodiments, the first deposition process comprises a physical vapor deposition process and the second deposition process comprises electron beam deposition. In certain embodiments, the first deposition process comprises ion assisted electron beam deposition. The method may further comprise depositing a capping layer on the first metal reflective layer before depositing the second metal reflective layer, the capping layer being deposited by the first deposition process. In certain embodiments, the capping layer comprises a metal that is different than silver. The method may further comprise depositing a nucleation layer on the capping layer before depositing the second metal reflective layer, the nucleation layer being deposited by the second deposition process. In certain embodiments, the second metal reflective layer is formed with a larger thickness than the first metal reflective layer.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a cross-sectional view of an exemplary light-emitting diode (LED) chip with a multiple layer reflective structure according to principles of the present disclosure.

FIG. 1B is a cross-sectional view of a portion of the LED chip of FIG. 1A taken from the superimposed dashed-line box 1B of FIG. 1A and illustrating details of the multiple layer reflective structure according to principles of the present disclosure.

FIG. 2 is a cross-sectional view of the multiple layer reflective structure of FIGS. 1A and 1B.

FIG. 3A is a cross-sectional view of the portion of the LED chip of FIG. 1B after a first metal reflective layer of the multiple layer reflective structure is formed.

FIG. 3B is a cross-sectional view of the portion of the LED chip of FIG. 3A at a subsequent fabrication step after a second metal reflective layer of the multiple layer reflective structure is formed in another deposition system.

FIG. 4A is a cross-sectional view of a portion of the LED chip of FIG. 1 after formation of the reflective structure and barrier layer before photolithography lift-off.

FIG. 4B is a cross-sectional view of a portion of the LED chip of FIG. 4A after lift-off of a photoresist and illustrating no edge damage defects according to aspects of the present disclosure.

FIG. 4C is a cross-sectional view of a portion of the LED chip of FIG. 4A after lift-off of the photoresist and further illustrating edge damage artifacts that are reduced in severity according to aspects of the present disclosure.

FIG. 5 is a cross-sectional view of a portion of an LED chip that is similar to the LED chip of FIG. 4C except the LED chip is formed with a conventional metal reflective layer.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to multiple layer reflective structures for LED chips and related methods. Multiple layer reflective structures include different metal reflective layers formed of the same metal but with different morphologies and/or grain structures. Exemplary structures include a first metal reflective layer formed by sputtering, and a second metal reflective layer of the same material and formed by a deposition process different from sputtering. Reflective structures may further include capping layers and/or nucleation layers between the first and second metal reflective layers of the same material.

An LED chip typically comprises an active LED structure or region that may have many different semiconductor layers arranged in different ways. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group Ill nitride-based material systems. Group Ill nitrides refer to those semiconductor compounds formed between nitrogen (N) and the elements in Group III of the periodic table, usually aluminum (AI), gallium (Ga), and indium (In). Gallium nitride (GaN) is a common binary compound. Group Ill nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group Ill-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. In certain applications, UV LEDs may also be provided with one or more lumiphoric materials to provide LED packages with aggregate emissions having a broad spectrum and improved color quality for visible light applications. Near-IR and/or IR wavelengths for LED structures of the present disclosure may have wavelengths above 700 nm, such as in a range from 750 nm to 1100 nm, or more.

The present disclosure can be useful for LED chips having a variety of geometries, such as vertical and/or flip-chip geometries. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described herein are applicable to flip-chip structures where anode and cathode connections are made from a same side of the LED chip for flip-chip mounting to another surface. In certain flip-chip embodiments, the growth substrate of the LED chip may form the intended light-exiting surface for the LED chip.

Light emitted by the active layer or region of an LED chip is typically initiated in multiple directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive”material may be configured to transmit at least 50% of emitted radiation of a desired wavelength.

In LED chip arrangements, reflective structures that embody mirrors may be formed along one side of an active LED structure to redirect light toward an opposing side in an intended emission direction. Such reflective structures may include a metal reflective layer formed on a layer of the active LED structure, for example the p-type layer or the n-type layer. In certain embodiments, the metal reflective layer may embody a sputtered metal layer, that is, the metal reflective layer is formed by sputter deposition. As known to those skilled in the art, a sputtered metal layer in an LED chip structure has a readily identifiable film structure or morphology by way of scanning electron microscopy (SEM) and/or focused ion beam (FIB) microscopy. For example, a sputtered metal layer may have a larger grain size than a metal layer of the same material formed by other common deposition techniques, such as electron beam deposition. In certain embodiments, other deposition techniques beyond sputtering may be utilized to provide a physical vapor deposited layer with larger grain size (e.g., different morphology). For example, the physical vapor deposited layer may be formed by ion assisted electron beam deposition or thermal evaporation, among other physical vapor deposition processes. In this manner, a sputtered metal layer or a physical vapor deposited layer may have a first morphology and another metal layer of the same material but formed by a different process, such as electron beam deposition, may have a second morphology that is different than the first morphology. The larger associated grain size may provide reduced surface cracking, fewer grain boundaries, and/or reduced discontinuities that may form regions for light absorption. In this manner, such a reflective layer may form an improved reflective surface in LED chips.

Despite the advantages of improved reflectivity, some sputtered metal layers may provide challenges during fabrication of LED chips. For example, the conformal nature of sputtering may increase instances of edge damage artifacts during photolithography lift-off steps. Edge damage artifacts may embody additional material, such as material tags, that extend from intended edges of layers after lift-off. In this manner, metal reflective layers formed by other deposition techniques, such as electron beam deposition, may form in a more line-of-sight manner that reduces occurrence of such edge damage artifacts.

According to aspects of the present disclosure, a hybrid metal reflective structure is employed that takes advantage of both types of deposition. In this manner, a multiple layer reflective structure may include a first metal reflective layer that embodies a sputtered metal layer and a second metal reflective layer of a same material that is not formed by sputtering. The first and second metal reflective layers may comprise various reflective metals, such as Ag or alloys thereof in the context of GaN-based LED structures. By forming a first sputtered metal layer of Ag, the improved reflective surface may be positioned proximate the active LED structure. Then, the remainder of the reflective structure may include a layer of Ag with a structure that reduces formation of edge damage artifacts during subsequent photolithography lift-off steps.

In certain embodiments, a thickness of the first metal layer that is sputtered is smaller than a thickness of the second metal layer. In this manner, while the thickness of the first metal layer is configured to be sufficient for reflectivity purposes, the thickness is purposefully kept as small as possible to mitigate edge damage artifacts. In certain embodiments, the thickness of the first metal reflective layer may be in a range from 200 angstroms (Å) to 1200 Å, or in a range from 200 Å to 800 Å. By comparison, a thickness of the second metal reflective layer may be in a range from 2000 Å to 8000 Å, or in a range from 2000 Å to 5000 Å. Since the second metal reflective layer is formed in a manner that reduces edge damage artifacts, the second metal reflective layer may even have larger thicknesses. In this manner, the second metal reflective layer may be at least twice the thickness of the first metal reflective layer. In still further embodiments, the second metal reflective layer may be at least three times, or at least four times, or at least five times, or up to at least ten times the thickness of the first metal reflective layer, depending on the embodiment. In certain embodiments, the thickness of the second metal layer may be at least the same thickness as the first metal reflective layer or thicker as specified above.

In certain embodiments, the reflective structure may further include a capping layer formed on the sputtered metal layer before removal from the sputtering system. In this manner, the capping layer may also be formed by sputter deposition. The capping layer may serve to protect the sputtered metal layer during transfer to another system, such as an electron beam system, for deposition of the remaining layers of the reflective structure. The capping layer may embody an inert layer that doesn't readily oxidize during system transfer. The selection of material for the capping layer may include any noble metal dissimilar from the sputtered metal layer. For example, when the sputtered metal layer comprises Ag or an alloy thereof, the capping layer may be formed by any of ruthenium (Ru), rhodium (Rh), palladium (Pd), osmium (Os), iridium (Ir), platinum (Pt), or gold (Au). In further embodiments, additional materials that are slightly less inert than the noble metals described above may still provide suitable capping, such as titanium (Ti), nickel (Ni), or tungsten (W), among others. The selection of materials above for the capping layer may permit the capping layer to have a relatively small thickness while still protecting the first metal reflective layer. For example, the capping layer may have a thickness in a range from 10 Å to 200 Å, or in a range from 10 Å to 50 Å. In certain embodiments, the capping layer may form in a discontinuous manner on the first metal reflective layer, particularly at the lower end of the thickness ranges.

In certain embodiments, the reflective structure may include a nucleation layer formed on the capping layer. The nucleation layer may embody a first deposition step once the structure is transferred to the other system (e.g., the electron beam system). The nucleation layer is positioned to enhance deposition of the second reflective layer, such as a second layer of Ag. The nucleation layer may be formed of Ti, chromium (Cr), conductive ceramics, and/or alloys such as aluminum zinc oxide (AZO) or indium tin oxide (ITO). As described herein, the capping layer and the nucleation layer are electrically conductive layers, comprised of metals or metallic compounds or other electrically conductive elements or compounds. In certain embodiments a thickness of the nucleation layer is also kept as small as possible, such as similar ranges as described above for the capping layer. In still further embodiments, the thickness of the nucleation layer is smaller than the capping layer. As with certain configurations of the capping layer, the nucleation layer may form in a discontinuous manner.

The function and position of the capping and nucleation layers, between first and second metal reflective layers of the same material, provides benefits for one or more of physical, mechanical, electrical, and optical properties of the overall reflective structure. Various benefits include tailoring film morphology, grain size, and/or packing efficiency, among others within the overall reflective structure.

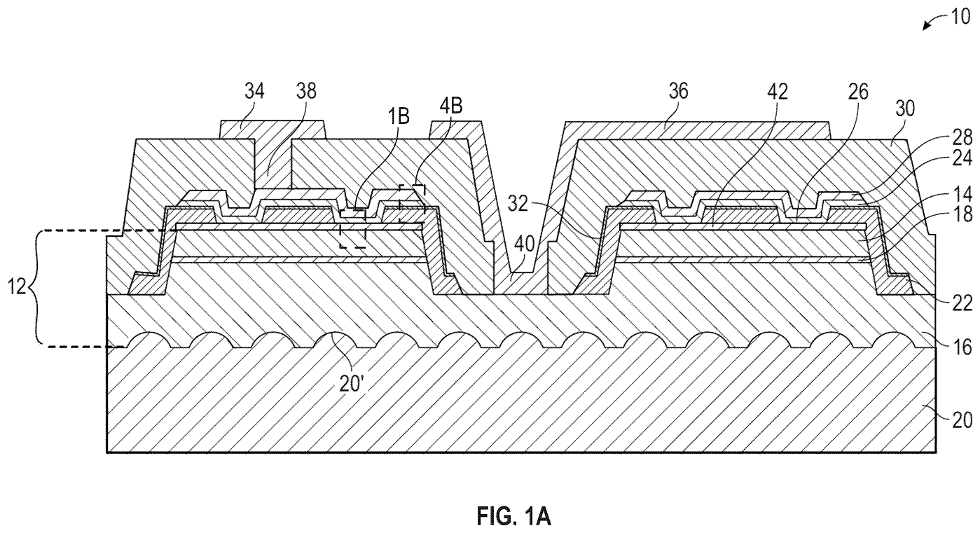

FIG. 1A is a cross-sectional view of an exemplary LED chip 10 according to principles of the present disclosure. The LED chip 10 includes an active LED structure 12 comprising a p-type layer 14, an n-type layer 16, and an active layer 18 therebetween. The active LED structure 12 may be formed on a substrate 20. In certain embodiments, one or more buffer layers and/or undoped layers may be provided between the substrate 20 and n-type layer 16 of the active LED structure 12. In certain embodiments, the n-type layer 16 is between the active layer 18 and the substrate 20. In other embodiments, the doping order may be reversed. The substrate 20 can comprise many different materials such as SiC or sapphire and can have one or more surfaces that are shaped, textured, or patterned to enhance light extraction. In certain embodiments, the substrate is light transmissive (preferably transparent) and may include a patterned surface 20′ that is proximate the active LED structure 12 and includes multiple recessed and/or raised features.

In FIG. 1A, a dielectric reflective layer 22 is provided on portions of the p-type layer 14. The dielectric reflective layer 22 may comprise many different materials and preferably comprises a material that presents an index of refraction step with the material of the active LED structure 12 to promote total internal reflection (TIR) of light generated from the active LED structure 12. Light that experiences TIR is redirected without experiencing absorption or loss and can thereby contribute to useful or desired LED chip emission. In certain embodiments, the dielectric reflective layer 22 comprises a material with an index of refraction lower than the index of refraction of the active LED structure 12 material. The dielectric reflective layer 22 may comprise many different materials, with some having an index of refraction less than 2.3, while others can have an index of refraction less than 2.15, less than 2.0, and less than 1.5. In certain embodiments, the dielectric reflective layer 22 comprises silicon dioxide (SiO₂) and/or silicon nitride (SiN). It is understood that many dielectric materials can be used such as SiN, SiNx, Si₃N₄, Si, germanium (Ge), SiO₂, SiOx, titanium dioxide (TiO₂), tantalum pentoxide (Ta₂O₅), ITO, magnesium oxide (MgOx), zinc oxide (ZnO), and combinations thereof. In certain embodiments, the dielectric reflective layer 22 may include multiple alternating layers of different dielectric materials, e.g., alternating layers of SiO₂ and SiN that symmetrically repeat or are asymmetrically arranged. Some Group Ill nitride materials such as GaN can have an index of refraction of approximately 2.4, SiO₂ can have an index of refraction of approximately 1.48, and SiN can have an index of refraction of approximately 1.9. Embodiments with the active LED structure 12 comprising GaN and the dielectric reflective layer 22 comprising SiO₂ may have a sufficient index of refraction step between the two to allow for efficient TIR of light. The dielectric reflective layer 22 may have different thicknesses depending on the type of materials used, with some embodiments having a thickness of at least 0.2 microns (μm). In some of these embodiments, the dielectric reflective layer 22 can have a thickness in the range of 0.2 μm to 0.7 μm, while in some of these embodiments the thickness can be approximately 0.5 μm. Portions of the dielectric reflective layer 22 may extend along mesa sidewalls of the active LED structure 12 and along sidewall portions of the p-type layer 14, the active layer 18, and the n-type layer 16.

The LED chip 10 may further include a reflective structure 24 that is on the dielectric reflective layer 22 such that the dielectric reflective layer 22 is arranged between the active LED structure 12 and the reflective structure 24. As described below in greater detail, the reflective structure 24 may embody a multiple layer metal reflective structure configured to reflect any light from the active LED structure 12 that may pass through the dielectric reflective layer 22. The reflective structure 24 can comprise many different materials such as Ag or alloys thereof, gold (Au) or alloys thereof, or combinations thereof. As illustrated, the reflective structure 24 may include one or more reflective layer interconnects 26 that provide electrically conductive paths through the dielectric reflective layer 22 to the p-type layer 14. In certain embodiments, the reflective layer interconnects 26 comprise reflective layer vias. In some embodiments, the reflective layer interconnects 26 comprise the same material as the reflective structure 24 and are formed at the same time as the reflective structure 24. In other embodiments, the reflective layer interconnects 26 may comprise a different material than the reflective structure 24.

The LED chip 10 may also comprise a barrier layer 28 on a side of the reflective structure 24 opposite the dielectric reflective layer 22 to prevent migration of the reflective structure 24 material, such as Ag, to other layers. Preventing this migration helps the LED chip 10 maintain efficient operation through its lifetime. The barrier layer 28 may comprise an electrically conductive material, with suitable materials including but not limited to sputtered Ti/Pt followed by evaporated Au bulk material or sputtered Ti/Ni followed by an evaporated Ti/Au bulk material.

A passivation layer 30 may be included on the barrier layer 28 as well as any portions of the reflective structure 24 that may be uncovered by the barrier layer 28. The passivation layer 30 may further be arranged on portions of the dielectric reflective layer 22 that are uncovered by the reflective structure 24. The passivation layer 30 protects and provides electrical insulation for the LED chip 10 and can comprise many different materials, such as a dielectric material. In certain embodiments, the passivation layer 30 is a single layer, and in other embodiments, the passivation layer 30 comprises a plurality of layers. A suitable material for the passivation layer 30 includes but is not limited to SiN, SiNx, and/or Si₃N₄. In certain embodiments, the dielectric reflective layer 22 comprises SiO₂ and the passivation layer 30 comprises SiN, SiNx, or Si₃N₄. In other embodiments, the dielectric reflective layer 22 and at least a portion of the passivation layer 30 may each comprise SiO₂. As illustrated, the dielectric reflective layer 22 may bound perimeter and/or sidewall portions of the active LED structure 12, including the p-type layer 14, the active layer 18, and the n-type layer 16, along a perimeter of the LED chip 10. Furthermore, the passivation layer 30 may be arranged to also bound perimeter portions of the active LED structure 12. In this manner, portions of the dielectric reflective layer 22 may be arranged between portions of the passivation layer 30 along sidewalls of active LED structure 12 for enhanced passivation and protection.

Certain embodiments may also comprise one or more adhesion layers 32 positioned at one or more interfaces between the dielectric reflective layer 22 and the reflective structure 24 to promote improved adhesion therebetween. Many different materials can be used for the adhesion layer 32, such as titanium oxide (TiO, TiO₂), titanium oxynitride (TiON, TiₓO_{y}N), tantalum oxide (TaO, Ta₂O₅), tantalum oxynitride (TaON), aluminum oxide (AlO, AlxOy) or combinations thereof, with a preferred material being TiON, AlO, or AlxOy. In certain embodiments, the adhesion layer 32 comprises AlₓO_{y}, where 1≤x≤4 and 1≤y≤6. In certain embodiments, the adhesion layer 32 comprises AlxOy, where x=2 and y=3, or Al₂O₃. The adhesion layer 32 may be deposited by electron beam deposition that may provide a smooth, dense, and continuous layer without notable variations in surface morphology. The adhesion layer 32 may also be deposited by sputtering, chemical vapor deposition, plasma enhanced chemical vapor deposition, or atomic layer deposition (ALD).

In FIG. 1A, the LED chip 10 comprises a p-contact 34 and an n-contact 36 that are arranged on the passivation layer 30 and are configured to provide electrical connections with the active LED structure 12. The p-contact 34, which may also be referred to as an anode contact, may comprise one or more p-contact interconnects 38 that extend through the passivation layer 30 to the barrier layer 28 or the reflective structure 24 to provide an electrical path to the p-type layer 14. In certain embodiments, the one or more p-contact interconnects 38 comprise one or more p-contact vias. The n-contact 36, which may also be referred to as a cathode contact, is electrically coupled to the n-type layer 16 by way of one or more n-contact interconnects 40 that extend through the passivation layer 30, the barrier layer 28, the dielectric reflector layer 22, the reflective structure 24, the p-type layer 14, and the active layer 18. In certain embodiments, the one or more n-contact interconnects 40 may be referred to as one or more n-contact vias. Openings for the n-contact interconnects 40 may be formed in a separate etching step than etching along the perimeter of the LED chip 10 where the passivation layer 30 bounds the active LED structure 12. For illustrative purposes, FIG. 1A is shown with a single n-contact interconnect 40. In practice, the LED chip 10 may include multiple n-contact interconnects 40 spaced apart in an array pattern across the active LED structure 12.

In operation, a signal applied across the p-contact 34 and the n-contact 36 is conducted to the p-type layer 14 and the n-type layer 16, causing the LED chip 10 to emit light from the active layer 18. The p-contact 34 and the n-contact 36 can comprise many different materials such as Au, copper (Cu), nickel (Ni), In, Al, Ag, tin (Sn), Pt, or combinations thereof. In still other embodiments, the p-contact 34 and the n-contact 36 can comprise conducting oxides and transparent conducting oxides such as ITO, nickel oxide (NiO), ZnO, cadmium tin oxide, indium oxide, tin oxide, magnesium oxide, ZnGa₂O₄, ZnO₂/Sb, Ga₂O₃/Sn, AgInO₂/Sn, In₂O₃/Zn, CuAlO₂, LaCuOS, CuGaO₂, and SrCu₂O₂. The choice of material used can depend on the location of the contacts and on the desired electrical characteristics, such as transparency, junction resistivity, and sheet resistance. In certain embodiments, the LED chip 10 is arranged for flip-chip mounting and the p-contact 34 and n-contact 36 are configured to be mounted or bonded to a surface, such as a printed circuit board. While FIG. 1A is described in the context of a flip-chip structure, the principles disclosed are readily applicable to other chip structures.

FIG. 1B is a cross-sectional view of a portion of the LED chip 10 of FIG. 1A taken from the superimposed dashed-line box 1B of FIG. 1A. In this portion of the LED chip 10, the reflective structure 24 is positioned between the p-type layer 14 and the barrier layer 28 and may form one of the reflective layer interconnects 26 of FIG. 1A. It is understood the details of the reflective structure 24 provided below are the same in other areas of the LED chip 10, such as on portions of the dielectric reflective layer 22 and/or adhesion layer 32.

As illustrated in FIG. 1B, the reflective structure 24 includes a first metal reflective layer 24-1 on the p-type layer 14 and on the dielectric reflective layer 22 and/or adhesion layer 32 in other portions of the LED chip 10 as illustrated in FIG. 1A. The first metal reflective layer 24-1 may comprise a first metal, such as Ag in certain embodiments. The first metal reflective layer 24-1 may embody a sputtered metal layer for providing an improved reflective surface to the p-type layer 14 and/or other portions of the active LED structure. A capping layer 46 may be formed on the first metal reflective layer 24-1 on a side opposite the p-type layer 14. The capping layer 46 may include any of the electrically conductive materials described above, such as noble metals or other metals with suitable inertness to protect the first metal reflective layer 24-1 during tool transfer. In certain embodiments, a nucleation layer 48 may be formed on the capping layer 46 after tool transfer to enhance deposition of a second metal reflective layer 24-2. The capping layer 46 may include any of the materials described above. The second metal reflective layer 24-2 may comprise the same metal as the first metal reflective layer 24-1 but formed by a deposition process that is different from sputtering. For example, the second metal reflective layer 24-2 may be formed by electron beam deposition to reduce edge damage artifacts during subsequent lift-off processes. In this regard, both the first and second metal reflective layers 24-1, 24-2 may comprise a same metal, such as Ag, but with different morphology structures. For example, the average grain size of the first metal reflective layer 24-1 may be larger than the average grain size of the second metal reflective layer 24-2. By separating the first and second metal reflective layers 24-1, 24-2 of the same material, a hybrid metal reflective structure is formed that takes advantage of both types of film morphologies and deposition techniques to provide an overall reflective structure 24 with increased reflectivity and reduced manufacturing defects.

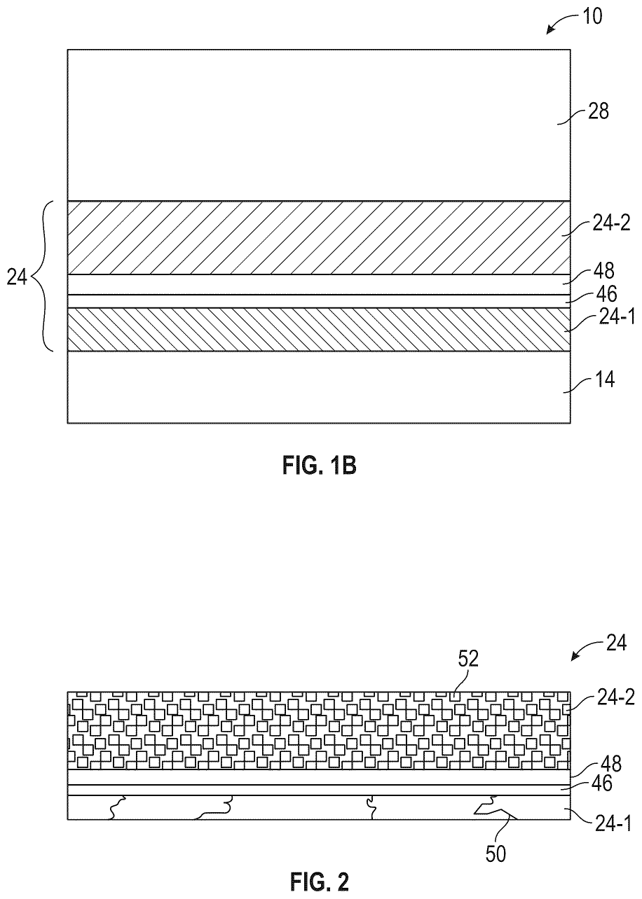

FIG. 2 is a cross-sectional view of the reflective structure 24 of FIGS. 1A and 1B illustrating details of the morphology differences between the first and second metal reflective layers 24-1, 24-2. As illustrated, the first metal reflective layer 24-1 has a structure with larger grain sizes and fewer associated grain boundaries 50. As described above, reduced grain boundaries 50 and/or discontinuities provides few regions for undesirable light absorption, thereby forming an increased reflective surface for the active LED structure 12 of FIG. 1A. In contrast, the second metal reflective layer 24-2 is formed with a much smaller grain structure 52 than the first metal reflective layer 24-1. Accordingly, the first and second metal reflective layers 24-1, 24-2 may be formed with the same metal while having different morphologies. The choice of the same metal for both first and second metal reflective layers 24-1, 24-2 may be advantageous by selecting a common metal with increased reflectivity tailored for a particular LED structure, such as Ag in the context of GaN-based active LED structures.

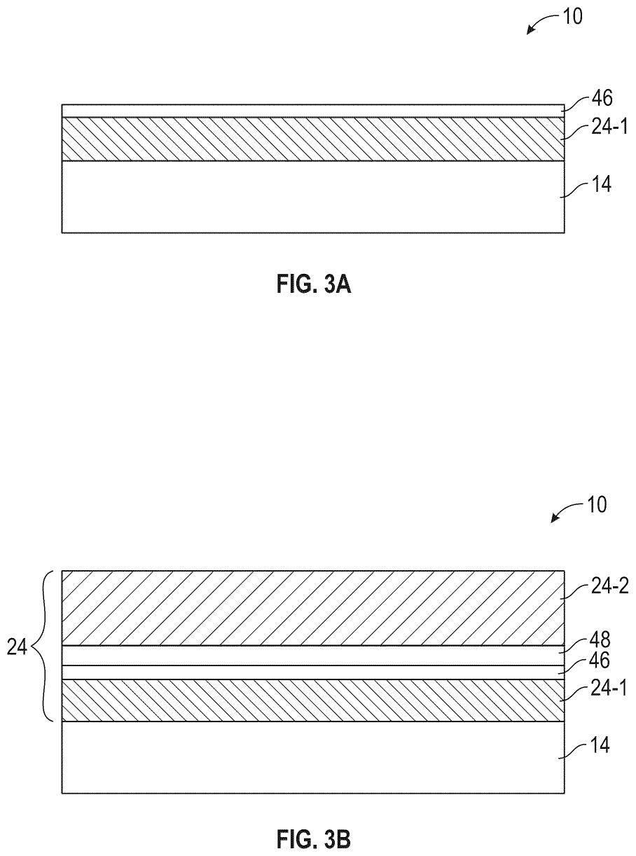

FIGS. 3A and 3B illustrate a sequential fabrication sequence for forming the reflective structure 24 with different metal deposition techniques. FIG. 3A is a cross-sectional view of the portion of the LED chip 10 of FIG. 1B after the first metal reflective layer 24-1 is formed. As described above, the first metal reflective layer 24-1 may be formed by sputtering such that the first metal reflective layer 24-1 embodies a sputtered metal layer. The capping layer 46 may then be formed in the same deposition system, also by sputtering. After sputtering of the first metal reflective layer 24-1 and the capping layer 46, the LED chip 10 may then be transferred to another deposition system that is different than a sputtering system. Alternatively, the first metal reflective layer 24-1 may be formed by another physical vapor deposition process, such as ion assisted electron beam deposition, that is configured to provide a morphology with larger grain size and increased reflectivity in a manner at least partially similar to sputtering. FIG. 3B is a cross-sectional view of the portion of the LED chip 10 of FIG. 3A at a subsequent fabrication step after the second metal reflective layer 24-2 is formed in another deposition system. After transfer to the next deposition system, such as an electron beam deposition system, the second metal reflective layer 24-2 may then be formed on the first metal reflective layer 24-1 with the capping layer 46 therebetween. In certain embodiments, the nucleation layer 48 may be formed first after the transfer, followed by the second metal reflective layer 24-2. In this regard, the nucleation layer 48 and the second metal reflective layer 24-2 may be formed by the same deposition technique (e.g., electron beam) that is different from the sputtering or alternative deposition technique of FIG. 3A.

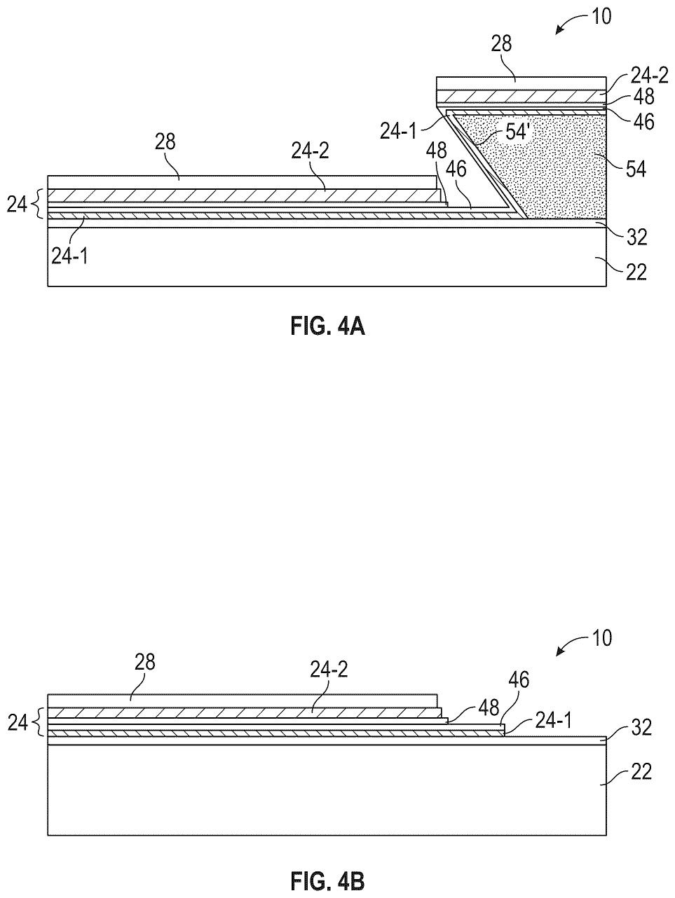

FIGS. 4A to 4C are cross-sectional views illustrating various fabrication steps where edge damage artifacts may be mitigated. The views provided are from portions of the LED chip 10 of FIG. 1 where edges of the reflective structure 24 and barrier layer 28 terminate on the dielectric reflective layer 22 and/or adhesion layer 32, such as the box labeled 4B of FIG. 1.

FIG. 4A is a cross-sectional view of a portion of the LED chip 10 of FIG. 1 after formation of the reflective structure 24 and barrier layer 28 and before photolithography lift-off. A photoresist 54 is in place on areas of the dielectric reflective layer 22 and/or adhesion layer 32 to define edge termination of the reflective structure 24 and barrier layer 28. Due to the nature of deposition for the first metal reflective layer 24-1 and the capping layer 46, these layers may conformally deposit along sidewalls 54′ of the photoresist 54. The different deposition process for the nucleation layer 48, second metal reflective layer 24-2, and barrier layer 28 is such that these layers do not necessarily form along sidewalls 54′ of the photoresist 54.

FIG. 4B is a cross-sectional view of a portion of the LED chip 10 of FIG. 4A after lift-off of the photoresist 54 and illustrating no edge damage defects according to aspects of the present disclosure. FIG. 4B illustrates embodiments after lift-off where the portions of the first metal reflective layer 24-1 and the capping layer 46 along the sidewalls 54′ of FIG. 4A are cleanly removed. In this manner, a well-defined edge of the first metal reflective layer 24-1 and the capping layer 46 may be formed over the dielectric reflective layer 22 and/or adhesion layer 32. By forming the first and second metal reflective layers 24-1, 24-2 according to different deposition techniques, the overall thickness of the first metal reflective layer 24-1 and/or capping layer 46 may be sufficiently thin to reduce formation of edge damage artifacts proximate locations where the sidewalls 54′ of the photoresist 54 were located in FIG. 4A. As further illustrated, a lateral edge of the second metal reflective layer 24-2 is inset relative to lateral edges of the first metal reflective layer 24-1 and the capping layer 46. That is, the first metal reflective layer 24-1 and capping layer 46 extend farther and/or cover more area of the underlying dielectric reflective layer 22 and/or adhesion layer 32 than the second metal reflective layer 24-2.

FIG. 4C is a cross-sectional view of a portion of the LED chip 10 of FIG. 4A after lift-off of the photoresist 54 and further illustrating edge damage artifacts that are reduced in severity according to aspects of the present disclosure. Instead of the clean lift-off of FIG. 4B, a portion 24-1′ of the first metal reflective layer 24-1 and/or a portion 46′ of the capping layer 46 in FIG. 4C may form a tag that extends or lifts up in a direction away from the dielectric reflective layer 22 during lift-off of the photoresist 54 of FIG. 4A, thereby forming an edge damage artifact. This may be due to slight tearing of the first metal reflective layer 24-1 and/or capping layer 46 during lift-off. However, as described above, the overall thickness of the first metal reflective layer 24-1 and/or capping layer 46 may be sufficiently thin to mitigate severity of the edge damage artifacts and reduce associated problems in the LED chip 10.

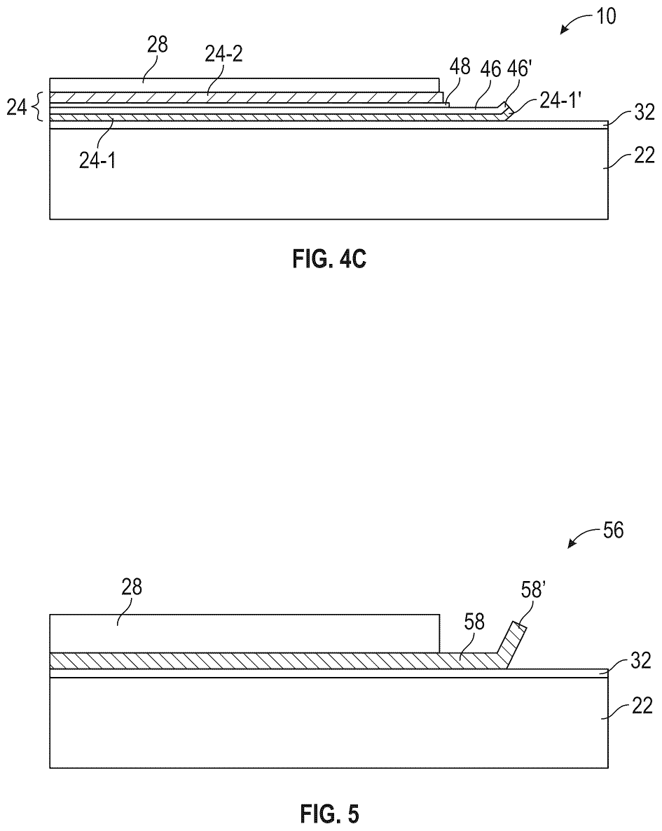

FIG. 5 is a cross-sectional view of a portion of an LED chip 56 that is similar to the LED chip 10 of FIG. 4C except the LED chip 56 is formed with a conventional metal reflective layer 58. By forming the entire metal reflective layer 58 according to the first deposition method, such as sputtering or other physical vapor depositions such as ion assisted electron beam deposition, the metal reflective layer 58 has substantially increased thickness compared with the first metal reflective layer 24-1 of FIG. 4C. In this regard, the thicker metal reflective layer 58 may similarly form on photoresist sidewalls and have greater mechanical integrity during lift-off. Accordingly, a larger portion 58′ of the metal layer 58 may form the edge damage artifact as illustrated in FIG. 5, which may interfere with subsequent structure of the LED chip 56, thereby creating reliability issues and/or reductions in brightness.

While the above-described embodiments are provided in the context of the flip-chip structure of FIG. 1A, the principles described are equally applicable to reflective structures in other LED chip geometries. For example, the aspects disclosed for the reflective structure including various combinations of the first metal reflective layer, the second metal reflective layer, the capping layer, and the nucleation layer may be implemented in LED chip structures with vertical contacts, lateral contacts, and LED chip structures with carrier submounts and growth substrates removed.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip comprising:
an active LED structure comprising an n-type layer, a p-type layer, and an active layer between the n-type layer and the p-type layer; and
a reflective structure on the active LED structure, the reflective structure comprising:
a first metal reflective layer on the active LED structure, the first metal reflective layer comprising a first morphology; and
a second metal reflective layer on the active LED structure, the second metal reflective layer comprising a same metal as the first metal reflective layer and a second morphology that is different than the first morphology.

2. The LED chip of claim 1, wherein the first morphology comprises a larger grain size than the second morphology.

3. The LED chip of claim 1, further comprising a capping layer between the first metal layer and the second metal layer, the capping layer comprising a different metal than the metal of the first and second metal reflective layers.

4. The LED chip of claim 3, wherein the metal of the first and second metal reflective layers comprises silver, and the metal of the capping layer comprises ruthenium, rhodium, palladium, osmium, iridium, platinum, or gold.

5. The LED chip of claim 3, wherein the metal of the first and second metal reflective layers comprises silver, and the metal of the capping layer comprises titanium, nickel, or tungsten.

6. The LED chip of claim 3, further comprising a nucleation layer between the second metal reflective layer and the capping layer.

7. The LED chip of claim 1, wherein the first metal reflective layer comprises a sputtered metal layer.

8. The LED chip of claim 1, wherein the first metal reflective layer comprises a physical vapor deposited layer.

9. The LED chip of claim 1, wherein the second metal reflective layer is thicker than first metal reflective layer.

10. The LED chip of claim 1, further comprising a dielectric reflective layer between the first metal reflective layer and the active LED structure, wherein a lateral edge of the second metal reflective layer is inset relative to a lateral edge of the first metal reflective layer on the dielectric reflective layer.

11. A light-emitting diode (LED) chip comprising:
an active LED structure comprising an n-type layer, a p-type layer, and an active layer between the n-type layer and the p-type layer; and
a reflective structure on the active LED structure, the reflective structure comprising:
a first metal reflective layer on the active LED structure, the first metal reflective layer formed of a first metal; and
a capping layer on the first metal reflective layer, the capping layer comprising a noble metal that is different than the first metal.

12. The LED chip of claim 11, wherein the noble metal comprises ruthenium, rhodium, palladium, osmium, iridium, platinum, or gold.

13. The LED chip of claim 12, wherein the first metal comprises silver or a silver alloy.

14. The LED chip of claim 11, wherein the reflective structure further comprises a second metal reflective layer formed of the first metal, and the capping layer is between the first metal reflective layer and the second metal reflective layer.

15. The LED chip of claim 14, wherein the first metal reflective layer comprises a different morphology than the second metal reflective layer.

16. The LED chip of claim 15, wherein the first metal comprises silver and the noble metal comprises gold.

17. The LED chip of claim 14, further comprising a nucleation layer between the second metal reflective layer and the capping layer.

18. The LED chip of claim 14, wherein the second metal reflective layer is at least the same thickness as the first metal reflective layer and up to ten times thicker than first metal reflective layer.

19. A method comprising:
providing an active light-emitting diode (LED) structure comprising an n-type layer, a p-type layer, and an active layer between the n-type layer and the p-type layer;
depositing a first metal reflective layer on the active LED structure with a first deposition process; and
depositing a second metal reflective layer on the first metal reflective layer with a second deposition process that is different than the first deposition process, the first metal reflective layer and the second metal reflective layer comprising silver.

20. The method of claim 19, wherein the first deposition process comprises sputtering and the second deposition process comprises electron beam deposition.

21. The method of claim 19, wherein the first deposition process comprises a physical vapor deposition process and the second deposition process comprises electron beam deposition.

22. The method of claim 21, wherein the first deposition process comprises ion assisted electron beam deposition.

23. The method of claim 19, further comprising depositing a capping layer on the first metal reflective layer before depositing the second metal reflective layer, the capping layer being deposited by the first deposition process.

24. The method of claim 23, wherein the capping layer comprises a metal that is different than silver.

25. The method of claim 23, further comprising depositing a nucleation layer on the capping layer before depositing the second metal reflective layer, the nucleation layer being deposited by the second deposition process.

26. The method of claim 19, wherein the second metal reflective layer is formed with a larger thickness than the first metal reflective layer.
